(19) United States
(12) Patent Application Publication
(10) Pub. No.: US 2025/0358544 A1
(43) Pub. Date: Nov. 20, 2025

(54) PHOTODETECTOR

(71) Applicant: Sony Semiconductor Solutions Corporation, Kanagawa (JP)

(72) Inventors: Chihiro Okada, Tokyo (JP); Yasuji Ikeda, Kanagawa (JP)

(73) Assignee: Sony Semiconductor Solutions Corporation, Kanagawa (JP)

(21) Appl. No.: 18/871,638

(22) PCT Filed: May 29, 2023
(86) PCT No.: PCT/JP2023/019897

§ 371 Date: Dec. 4, 2024

(30) Foreign Application Priority Data
Jun. 15, 2022 (JP) 2022-096651

(51) Int. Cl. H04N 25/773; G01J 1/44; H04N 25/47; H10F 39/00

(52) U.S. Cl. CPC H04N 25/773; G01J 1/44; G01J 2001/442; G01J 2001/4466; H04N 25/47; H10F 39/809

(57) ABSTRACT

There is provided a light detecting device including: a pixel comprising a light receiving element; and a pixel circuit comprising a counter circuit and a control circuit. The light receiving element is configured to receive light. The counter circuit is configured to receive a first signal based on an output of the light receiving element. The counter circuit is configured to output a second signal based on a difference between a number of first signals in a first period and a number of first signals in a second period. The control circuit is configured to control the counter circuit.

### CROSS REFERENCE TO RELATED APPLICATIONS

This application claims the benefit of Japanese Priority Patent Application JP 2022-096651 filed Jun. 15, 2022, the entire contents of which are incorporated herein by reference.

### TECHNICAL FIELD

The present disclosure relates to a photodetector.

### BACKGROUND ART

PTL 1 proposes a device that includes a plurality of pixels and detects light. The plurality of pixels each includes a single photon avalanche diode (SPAD) element and a counter circuit.

### CITATION LIST

### Patent Literature

PTL 1: JP 2019-161551

### SUMMARY

### Technical Problem

A light detecting device is requested to have improved detection performance.

It is desirable to provide a light detecting device having favorable detection performance.

### Solution to Problem

A light detecting device according to an embodiment of the present disclosure includes: a pixel comprising a light receiving element; and a pixel circuit comprising a counter circuit and a control circuit. The light receiving element is configured to receive light. The counter circuit is configured to receive a first signal based on an output of the light receiving element. The counter circuit is configured to output a second signal based on a difference between a number of first signals in a first period and a number of first signals in a second period. The control circuit is configured to control the counter circuit.

A light detecting device according to an embodiment of the present disclosure includes: a pixel comprising a light receiving element; and a pixel circuit comprising a counter circuit and a control circuit. The light detecting device is configured to detect an intensity signal and a motion signal.

An electronic apparatus according to an embodiment of the present disclosure comprises a signal processor and a light detecting device. The light detecting device comprises: a pixel comprising a light receiving element; and a pixel circuit comprising a counter circuit and a control circuit. The light receiving element is configured to receive light. The counter circuit is configured to receive a first signal based on an output of the light receiving element and output a second signal based on a difference between a number of first signals in a first period and a number of first signals in a second period. The control circuit is configured to control the counter circuit.

### BRIEF DESCRIPTION OF DRAWINGS

FIG. 1 is a diagram illustrating an example of a schematic configuration of a photodetector according to an embodiment of the present disclosure.

FIG. 2 is a diagram illustrating a configuration example of the photodetector according to the embodiment of the present disclosure.

FIG. 3 is a block diagram illustrating a configuration example of the photodetector according to the embodiment of the present disclosure.

FIG. 4 is a timing chart illustrating an operation example of the photodetector according to the embodiment of the present disclosure.

FIG. 5 is a flowchart illustrating an operation example of the photodetector according to the embodiment of the present disclosure.

FIG. 6 is a schematic diagram illustrating an example of a cross-sectional configuration of the photodetector according to the embodiment of the present disclosure.

FIG. 7 is a diagram illustrating a configuration example of a photodetector according to a modification example 1 of the present disclosure.

FIG. 8 is a diagram illustrating a configuration example of a photodetector according to a modification example 2 of the present disclosure.

FIG. 9 is a diagram illustrating another configuration example of the photodetector according to the modification example 2 of the present disclosure.

FIG. 10 is a timing chart illustrating an operation example of a photodetector according to a modification example 3 of the present disclosure.

FIG. 11 is a diagram illustrating a configuration example of a photodetector according to a modification example 4 of the present disclosure.

FIG. 12 is a block diagram depicting an example of schematic configuration of a vehicle control system.

FIG. 13 is a diagram of assistance in explaining an example of installation positions of an outside-vehicle information detecting section and an imaging section.

FIG. 14 is a view depicting an example of a schematic configuration of an endoscopic surgery system.

FIG. 15 is a block diagram depicting an example of a functional configuration of a camera head and a camera control unit (CCU).

### DESCRIPTION OF EMBODIMENTS

The following describes an embodiment of the present disclosure in detail with reference to the drawings. It is to be noted that description is given in the following order.
1. Embodiment
2. Modification Examples
3. Usage Examples
4. Practical Application Examples

### 1. Embodiment

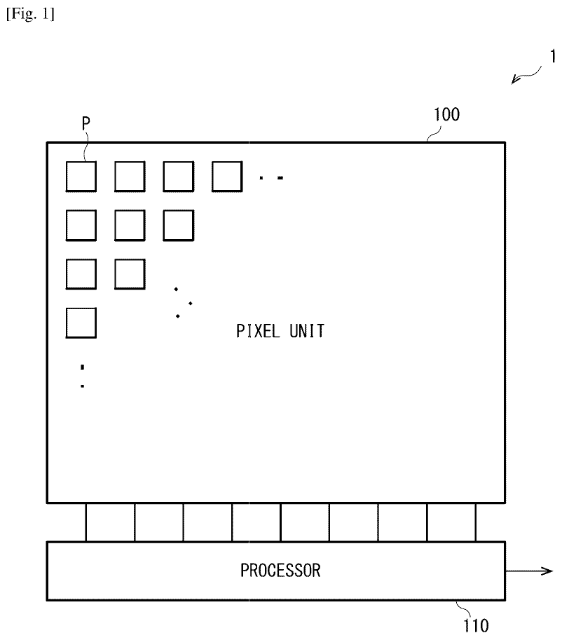

FIG. 1 is a diagram illustrating an example of a schematic configuration of a photodetector according to an embodiment of the present disclosure. The photodetector 1 is a device configured to detect incident light (i.e., a light detecting device). The photodetector 1 includes a plurality of pixels P. The plurality of pixels P each includes a light receiving element. The photodetector 1 is configured to photoelectrically convert the incident light and generate a signal. The photodetector 1 is a sensor configured to detect an event. The photodetector 1 may be applied, for example, as an event-driven sensor (referred to as an event vision sensor (EVS), an event driven sensor (EDS), a dynamic vision sensor (DVS), or the like).

In the example illustrated in FIG. 1, the photodetector 1 includes a region (pixel unit 100) in which the plurality of pixels P is two-dimensionally disposed in a matrix. The light receiving element (light receiving section) of each of the pixels P is, for example, an SPAD element. The photodetector 1 takes in incident light (image light) from a measurement target through an optical system (not illustrated) including an optical lens. The light receiving element may receive light, generate electric charge through photoelectric conversion, and generate a photocurrent.

The photodetector 1 includes a processor 110 configured to perform signal processing. The processor 110 is a signal processing circuit. The processor 110 performs signal processing (information processing). The processor 110 performs various kinds of signal processing on the signal of each of the pixels. The processor 110 outputs the signal of the pixel subjected to the signal processing. Although described below, the processor 110 may generate and output a signal related to a motion of the measurement target and a signal related to an intensity value. An intensity value (e.g., an intensity value associated with a pixel, such as an R pixel, a G pixel, or a B pixel) may also be referred to herein as a grayscale value.

The processor 110 is also a controller. The processor 110 is configured to control each unit of the photodetector 1. The processor 110 includes a plurality of circuits including, for example, a timing generator, a shift register, an address decoder, and the like. The timing generator generates a variety of timing signals. The processor 110 may supply each of the pixels P with a signal for driving the pixel P and control an operation of the pixel P.

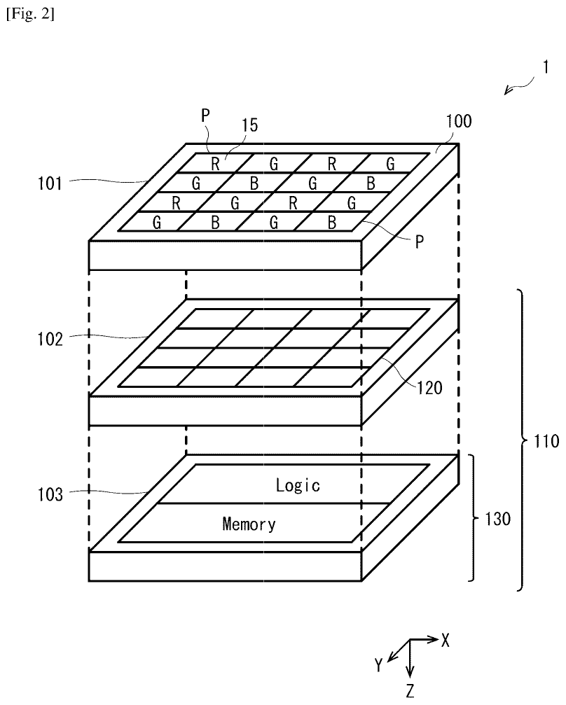

FIG. 2 is a diagram illustrating a configuration example of the photodetector according to the embodiment. As illustrated in FIG. 2, the photodetector 1 includes a first substrate 101, a second substrate 102, and a third substrate 103. The first substrate 101, the second substrate 102, and the third substrate 103 are stacked on top of each other. First substrate 101 is stacked on top of second substrate 102. Second substrate 102 is stacked on top of third substrate 103.

The photodetector 1 has a structure (stacked structure) in which the first substrate 101, the second substrate 102, and the third substrate 103 are stacked in a Z axis direction. It is to be noted that, as illustrated in FIG. 2, an incidence direction of light from an object which is the measurement target is defined as the Z axis direction, a left/right direction of the diagram orthogonal to the Z axis direction is defined as an X axis direction, and a direction orthogonal to the Z axis direction and the X axis direction is defined as a Y axis direction. In the following diagrams, a direction is sometimes expressed with reference to a direction of an arrow in FIG. 2.

The first substrate 101 is provided with the pixel unit 100. In the pixel unit 100, the plurality of pixels P is disposed in a horizontal direction (row direction) that is a first direction and a vertical direction (column direction) that is a second direction orthogonal to the first direction. Each of the pixels P in the pixel unit 100 includes a filter 15. The filter 15 is configured to selectively transmit light in a specific wavelength range among the pieces of incident light. The filter 15 is an RGB color filter, a filter that transmits infrared light, or the like. Each of the pixels P is a pixel including a light receiving element configured to receive visible light and output a photocurrent, a pixel including a light receiving element configured to receive invisible light (also referred to as non-visible light) and output a photocurrent, or the like.

In one example, the plurality of pixels P in the pixel unit 100 includes a pixel (R pixel) including the filter 15 that transmits light in a wavelength range for red, a pixel (G pixel) including the filter 15 that transmits light in a wavelength range for green, and a pixel (B pixel) including the filter 15 that transmits light in a wavelength range for blue. The R pixels, the G pixels, and the B pixels are disposed, for example, in accordance with a so-called Bayer arrangement. The R pixel, the G pixel, and the B pixel are configured to generate a signal of an R component, a signal of a G component, and a signal of a B component, respectively. It is possible to obtain RGB pixel signals on the basis of electric charge resulting from photoelectric conversion by the R pixel, the G pixel, and the B pixel.

It is to be noted that the filters provided in the pixels P are not limited to color filters for primary colors (RGB). The pixels P may include, for example, color filters for complementary colors such as cyan (Cy), magenta (Mg), and yellow (Ye). In addition, it is also possible to refrain from providing the filters 15 in a portion or all of the pixels P of the photodetector 1.

The second substrate 102 and the third substrate 103 are provided with the processor 110. As illustrated in FIG. 2, the processor 110 includes a pixel circuit unit 120 and a signal processing unit 130. The pixel circuit unit 120 and the signal processing unit 130 are separately disposed in the second substrate 102 and the third substrate 103. In the example illustrated in FIG. 2, the pixel circuit unit 120 is disposed in the second substrate 102. The signal processing unit 130 includes a logic circuit, a memory, and the like. The signal processing unit 130 is disposed in the third substrate 103.

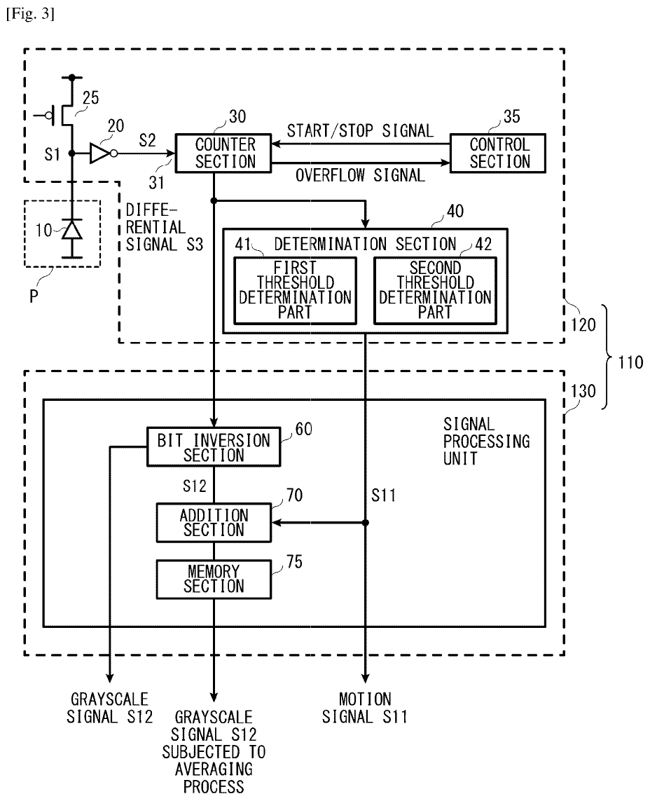

FIG. 3 is a block diagram illustrating a configuration example of the photodetector according to the embodiment. The photodetector 1 includes the pixel P and the processor 110. The pixel P includes a light receiving element 10. The processor 110 includes the pixel circuit unit 120 and the signal processing unit 130. In the example illustrated in FIG. 3, the pixel circuit unit 120 includes a generation section (also referred to as a generation circuit) 20, a supply section (also referred to as a supply circuit) 25, a counter section (also referred to as a counter circuit) 30, a control section (also referred to as a control circuit) 35, and a determination section (also referred to as a determination circuit) 40. The pixel circuit unit 120 is provided for each of the pixels P.

The light receiving element 10 is configured to receive light and generate a signal. The light receiving element 10 is an SPAD element. The light receiving element 10 may convert an incident photon into electric charge and output a signal S1 that is an electric signal corresponding to the incident photon. It is to be noted that the light receiving element 10 is also referred to as a photoelectric conversion element (photoelectric conversion section) configured to photoelectrically convert light.

The light receiving element 10 is electrically coupled, for example, to a power supply line, an electrode, or the like that allows a predetermined voltage to be supplied. In the example illustrated in FIG. 3, a cathode that is one of electrodes of the light receiving element 10 is electrically coupled to the power supply line through the supply section 25. A power supply voltage is supplied through the power supply line. An anode that is another electrode of the light receiving element 10 is electrically coupled to a ground line side or large negative voltage source.

The voltage supplied through the supply section 25 may cause a voltage serving as a potential difference larger than a breakdown voltage of the light receiving element 10 to be applied between the cathode and the anode of the light receiving element 10. In other words, a potential difference between both ends of the light receiving element 10 may be set to the potential difference larger than the breakdown voltage. In a case where a reverse bias voltage larger than the breakdown voltage is applied to the light receiving element 10, the light receiving element 10 is operable in a Geiger mode. In the light receiving element 10 in the Geiger mode, an avalanche multiplication phenomenon may occur in response to incidence of a photon and a pulsed current may be generated. In the pixel P, the signal S1 corresponding to a photocurrent flowing through the light receiving element 10 in response to the incidence of the photon is outputted to the generation section 20.

The generation section 20 is configured to generate a signal S2 based on the signal S1 generated by the light receiving element 10. In the example illustrated in FIG. 3, the generation section 20 includes an inverter. The generation section 20 includes a PMOS transistor and an NMOS transistor coupled in series. An input part of the generation section 20 is electrically coupled to the cathode of the light receiving element 10 and the supply section 25. An output part of the generation section 20 is electrically coupled to an input part 31 of the counter section 30.

The generation section 20 receives the signal S1 from the light receiving element 10. A signal level of the signal S1 changes in accordance with the current flowing through the light receiving element 10. In other words, a voltage (potential) of the signal S1 changes in accordance with the current flowing through the light receiving element 10. For example, in a case where the voltage of the signal S1 is higher than a threshold, the generation section 20 outputs the low-level signal S2. In addition, in a case where the voltage of the signal S1 is smaller than the threshold, the generation section 20 outputs the high-level signal S2. The generation section 20 may output the signal S2 serving as a pulse signal based on the voltage of the signal S1 to the counter section 30.

In the example illustrated in FIG. 3, in a case where the light receiving element 10 receives a photon and this causes the signal S1 to have a voltage smaller than a threshold voltage of the inverter serving as the generation section 20, the inverter causes a voltage of the signal S2 to transition from a low level to a high level. It is to be noted that the generation section 20 may include a buffer circuit, an AND circuit, and the like.

The supply section 25 is configured to supply the light receiving element 10 with a voltage and a current. The supply section 25 is electrically coupled to the power supply line through which the power supply voltage is provided. The supply section 25 may supply the light receiving element 10 with the voltage and the current. In the example illustrated in FIG. 3, the supply section 25 includes a PMOS transistor. It is to be noted that the supply section 25 may include a resistor.

In a case where the occurrence of avalanche multiplication causes a potential difference between the electrodes of the light receiving element 10 to be smaller than the breakdown voltage, the supply section 25 may supply the light receiving element 10 with the current. The supply section 25 recharges the light receiving element 10 to allow the light receiving element 10 to operate in the Geiger mode again. The supply section 25 is a recharge section. In other words, the supply section 25 recharges the light receiving element 10 with electric charge and recharges the voltage of the light receiving element 10.

The counter section 30 is configured to perform counting in accordance with a received signal. The counter section 30 includes the one input part 31 (input terminal). The counter section 30 counts pulses of a signal received by the input part 31. In the example illustrated in FIG. 3, the input part 31 of the counter section 30 receives the signal S2 that is a pulse signal. The counter section 30 is configured to count pulses of the signal S2 and output a signal based on a difference in the number of pulses of the signal S2 (also referred to as the number of signals S2) between two periods. The counter section 30 is provided for each of the pixels P. The counter section 30 includes, for example, an up-down counter.

The control section 35 is configured to control the counter section 30. The control section 35 includes a timing generator. The control section 35 is provided for each of the pixels P. The control section 35 is a timing control section. The control section 35 generates a timing signal, for example, on the basis of a clock signal, a synchronization signal, and the like received from outside and controls an operation of the counter section 30.

The control section 35 outputs a signal (start signal) for an instruction (request) to start counting to the counter section 30 and controls a timing for the counter section 30 to start counting. In addition, the control section 35 outputs a signal (stop signal) for an instruction to finish counting to the counter section 30 and controls a timing for the counter section 30 to finish counting. The control section 35 may also control the supply section 25. It is to be noted that the supply section 25 may be controlled by a control circuit different from the control section 35.

In the example illustrated in FIG. 3, the control section 35 receives an overflow signal from the counter section 30 as a signal (detection signal) indicating that a count value of the counter section 30 reaches a reference value. The overflow signal is a signal indicating an overflow of the count value. In other words, the overflow signal is a signal indicating an overflow of the amount of light received by the light receiving element 10. The control section 35 supplies the counter section 30 with the stop signal generated on the basis of the overflow signal to control the counter section 30.

In one example, in a case where the start signal is inputted to the counter section 30 from the control section 35, the counter section 30 starts counting in a first period Ta. The counter section 30 counts up the number of pulses of the signal S2 in the first period Ta. In a case where the count value of the counter section 30 reaches the reference value, the counter section 30 outputs, to the control section 35, the overflow signal indicating that the count value reaches the reference value and starts counting in a second period Tb. The counter section 30 uses the reference value as an initial value and counts down the number of pulses of the signal S2 in the second period Tb. The overflow signal that is the detection signal is a signal indicating an end of the first period Ta and a start of the second period Tb.

The control section 35 generates the stop signal in accordance with the overflow signal received from the counter section 30. The control section 35 outputs the stop signal to the counter section 30. The control section 35 outputs the stop signal indicating an end of the second period Tb to the counter section 30 to equalize respective lengths of the first period Ta and the second period Tb. In a case where the stop signal is inputted to the counter section 30 from the control section 35, the counter section 30 finishes counting in the second period Tb.

The counter section 30 generates and outputs a signal (differential signal S3) based on a difference between the number of pulses of the signal S2 in the first period Ta and the number of pulses of the signal S2 in the second period Tb. The counter section 30 may output, as the differential signal S3, a signal indicating a count value corresponding to the difference between the number of pulses of the signal S2 in the first period Ta and the number of pulses of the signal S2 in the second period Tb. For example, a signal value or a count value of the differential signal S3 is a value obtained by subtracting a count value counted down from a count value counted up.

The determination section 40 is configured to determine the magnitude of the difference in the number of pulses on the basis of the differential signal S3. The determination section 40 is configured to determine, for example, whether or not the signal value of the differential signal S3 is larger than a predetermined threshold. In the example illustrated in FIG. 3, the determination section 40 includes a first threshold determination part 41 and a second threshold determination part 42.

The first threshold determination part 41 is configured to compare a value of the differential signal S3 and a first threshold. The second threshold determination part 42 is configured to compare the value of the differential signal S3 and a second threshold. For example, the first threshold determination part 41 is configured to determine whether or not the signal value of the differential signal S3 or a value obtained by subtracting the count value in the second period Tb from the count value in the first period Ta is smaller than the first threshold. The second threshold determination part 42 is configured to determine whether or not the signal value of the differential signal S3 is larger than second threshold.

In a case where the signal value of the differential signal S3 falls below the first threshold, the first threshold determination part 41 determines that the motion of the object serving as the measurement target causes a positive event to occur. In a case where the signal value of the differential signal S3 does not fall below the first threshold, the first threshold determination part 41 determines that no positive event occurs. In a case where the signal value of the differential signal S3 exceeds the second threshold, the second threshold determination part 42 determines that the motion of the measurement target causes a negative event to occur. In a case where the signal value of the differential signal S3 does not exceed the second threshold, the second threshold determination part 42 determines that no negative event occurs.

In this way, the determination section 40 may detect presence or absence of occurrence of an event on the basis of the differential signal S3. In a case where the signal value of the differential signal S3 is smaller than the first threshold or larger than the second threshold, the determination section 40 determines that an event occurs. In other words, in a case where the amount of received light changed by the motion of the measurement target causes the amount of change in the count value to exceeds an upper limit or lower limit threshold, the determination section 40 determines that an event is “present”.

The determination section 40 generates and outputs the signal (motion signal) related to the motion of the measurement target on the basis of results of determinations made by the first threshold determination part 41 and the second threshold determination part 42. The determination section 40 outputs, to the signal processing unit 130, a signal indicating the signal value (count value) of the differential signal S3 and the presence or absence of the occurrence of an event, for example, as a motion signal S11. The motion signal S11 may include a signal indicating presence or absence of occurrence of a positive event and a negative event.

The signal processing unit 130 is configured to acquire the differential signal S3 and the motion signal S11 of each of the pixels P and execute signal processing. The signal processing unit 130 is a signal processing circuit. The signal processing unit 130 may perform various kinds of signal processing by using the differential signal S3 and the motion signal S11. In the example illustrated in FIG. 3, the signal processing unit 130 includes a bit inversion section 60, an addition section 70, and a memory section 75.

The bit inversion section 60 is configured to invert a bit value of a received signal. In the example illustrated in FIG. 3, the bit inversion section 60 receives the differential signal S3 from the counter section 30. The bit inversion section 60 inverts a bit value of the differential signal S3. The bit inversion section 60 generates a signal (grayscale signal) based on a sum of the number of pulses of the signal S2 in the first period Ta and the number of pulses of the signal S2 in the second period Tb.

The grayscale signal S12 has, for example, a signal value obtained by adding the count value in the second period Tb to the count value in the first period Ta. The grayscale signal S12 is a signal indicating a grayscale. In other words, the bit inversion section 60 restores the grayscale signal S12 indicating a grayscale value of a pixel by using the differential signal S3. The bit inversion section 60 performs an inversion process on the differential signal S3 of each of the pixels P and generates the grayscale signal S12 of the pixel P.

The addition section 70 and the memory section 75 receive the grayscale signal S12 of each of the pixels P from the bit inversion section 60. In addition, the addition section 70 and the memory section 75 receive the motion signal S11 of each of the pixels P from the determination section 40. The memory section 75 is configured to hold a signal of each of the pixels. The memory section 75 is a frame memory. The memory section 75 may store (record) the grayscale signals S12 and the motion signals S11 of each of the pixels in units of frames.

The addition section 70 is configured to perform a process of adding signals of pixels. The addition section 70 estimates a movement direction of a moving target by using, for example, the motion signal S11 of each of the pixels P. The addition section 70 aligns the grayscale signals S12 of each of the pixels P with reference to the grayscale signals S12 held in the memory section 75 on the basis of a result of the estimation. The addition section 70 performs processes of adding and averaging the plurality of grayscale signals S12.

The addition section 70 is an averaging section. The addition section 70 averages the plurality of grayscale signals S12 as described above and generates the averaged grayscale signal S12. Performing a process of integrating the plurality of grayscale signals S12 makes it possible to improve an S/N ratio of the grayscale signal S12. In this way, the signal processing unit 130 may acquire the motion signal S11, the grayscale signal S12, and the averaged grayscale signal S12 and output the motion signal S11, the grayscale signal S12, and the averaged grayscale signal S12 to the outside of the photodetector 1.

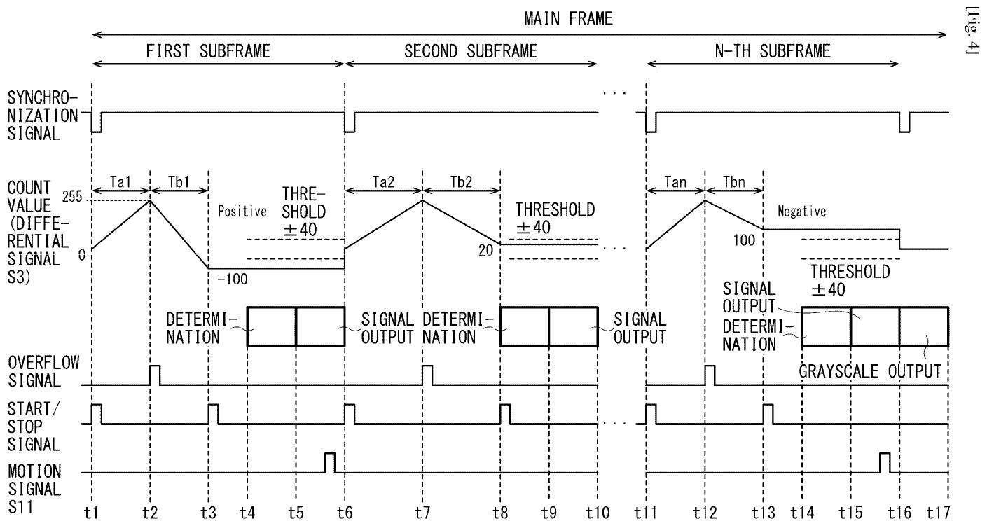

FIG. 4 is a timing chart illustrating an operation example of the photodetector according to the embodiment. FIG. 4 schematically illustrates the synchronization signal, the count value of the counter section 30, the overflow signal, the start/stop signal, and the motion signal S11 on the same time axis. The synchronization signal is generated, for example, on the basis of an imaging frame rate. The synchronization signal indicates a time interval of a subframe in a main frame. The control section 35 generates the start signal in synchronization with the synchronization signal. The control section 35 outputs the start signal to the counter section 30.

FIG. 4 illustrates an example of a case where the counter section 30 is an 8-bit up-down counter circuit. A period from a time t1 to a time t2, a period from a time t6 to a time t7, and a period from a time t11 to a time t12 are the first periods Ta (a first period Ta1 to a first period Tan in FIG. 4) described above. In each of these periods, the counter section 30 counts up the number of pulses of the signal S2.

A period from the time t2 to a time t3, a period from the time t7 to a time t8, and a period from the time t12 to a time t13 are the second periods Tb (a second period Tb1 to a second period Tbn in FIG. 4) described above. In each of these periods, the counter section 30 counts down the number of pulses of the signal S2. In FIG. 4, the first period Ta1 and the second period Tb1 have the same time interval. In addition, a first period Ta2 and a second period Tb2 have the same time interval. The first period Tan and the second period Tbn have the same time interval.

At the time t1 in a first subframe, the counter section 30 starts to count up the pulses of the signal S2 in accordance with the start signal received from the control section 35. In a case where the count value reaches “255”, which is a reference value, at the time t2, the counter section 30 outputs the overflow signal to the control section 35. In addition, “255” is set as the initial value for down-counting. The overflow signal serves as a signal indicating timings of an end of the first period Ta1 and a start of the second period Tb1.

At the time t2, the counter section 30 starts to count down the pulses of the signal S2. The control section 35 learns the length of the first period Ta1 on the basis of the start signal and the overflow signal. The control section 35 generates the stop signal and supplies the stop signal to the counter section 30 to equalize the length of the second period Tb1 to the length of the first period Ta1.

At the time t3, the counter section 30 finishes counting down the pulses of the signal S2 in accordance with the stop signal received from the control section 35. The counter section 30 outputs the differential signal S3 indicating a count value “−100”, which is a difference value between the count value obtained by counting up the pulses in the first period Ta1 and the count value obtained by counting down the pulses in the second period Tb1.

In a period from a time t4 to a time t5, the determination section 40 compares “−100” and “±40”. “−100” is a value of the differential signal S3. “±40” is a threshold. The first threshold determination part 41 determines that the signal value “−100” of the differential signal S3 is lower than the first threshold “−40” and detects that the motion of the measurement target causes a positive event to occur. It is to be noted that the signal value “8−100” of the differential signal S3 does not exceed the second threshold “+40”. The second threshold determination part 42 thus determines that no negative event occurs.

In a period from the time t5 to the time t6, the determination section 40 generates the motion signal S11 indicating the signal value of the differential signal S3 and the occurrence of a positive event in accordance with the results of the determinations made by the first threshold determination part 41 and the second threshold determination part 42. The bit inversion section 60 of the signal processing unit 130 performs the inversion process on the bit value of the differential signal S3 and generates the grayscale signal S12. The signal processing unit 130 outputs the motion signal S11 of each of the pixels P generated in the first subframe to the outside. In addition, the signal processing unit 130 may output the grayscale signal S12 of each of the pixels P generated in the first subframe to the outside. The signal processing unit 130 causes the memory section 75 to hold the grayscale signal S12 and the motion signal S11 of each of the pixels P in the first subframe.

At the time t6 in a second subframe, the count value of the counter section 30 is reset. The counter section 30 starts to count up the pulses of the signal S2 in accordance with the start signal. In a case where the count value reaches the reference value “255” at the time t7, the counter section 30 outputs the overflow signal to the control section 35. “255” is set as the initial value for down-counting.

At the time t7, the counter section 30 starts to count down the pulses of the signal S2. The control section 35 learns the length of the first period Ta2 by using the overflow signal. The control section 35 generates the stop signal and supplies the stop signal to the counter section 30 to equalize the length of the second period Tb2 to the length of the first period Ta2.

At the time t8, the counter section 30 finishes counting down the pulses of the signal S2 in accordance with the stop signal. The counter section 30 outputs the differential signal S3 indicating a difference value “+20” between the count value in the first period Ta2 and the count value in the second period Tb2.

In a period from the time t8 to a time t9, the determination section 40 compares a value “+20” of the differential signal S3 and the threshold “±40”. The first threshold determination part 41 and the second threshold determination part 42 each determine that the value of the differential signal S3 falls within the threshold and determine that no positive event or no negative event occurs.

In a period from the time t9 to a time t10, the determination section 40 generates the motion signal S11 indicating the signal value of the differential signal S3 and indicating that no event occurs. The bit inversion section 60 performs the inversion process on the bit value of the differential signal S3 and generates the grayscale signal S12. The signal processing unit 130 outputs the motion signal S11 of each of the pixels P generated in the second subframe to the outside. The signal processing unit 130 may also output the grayscale signal S12 of each of the pixels P generated in the second subframe to the outside. In addition, the signal processing unit 130 causes the memory section 75 to hold the grayscale signal S12 and the motion signal S11 of each of the pixels P in the second subframe.

At the time t11 in an N-th subframe illustrated in FIG. 4, the count value of the counter section 30 is reset. After that, the counter section 30 starts to count up the pulses of the signal S2 in accordance with the start signal. In a case where the count value reaches the reference value “255” at the time t12, the counter section 30 outputs the overflow signal to the control section 35. “255” is set as the initial value for down-counting.

At the time t12, the counter section 30 starts to count down the pulses of the signal S2. The control section 35 learns the length of the first period Tan by using the overflow signal. The control section 35 supplies the stop signal to the counter section 30 to equalize the length of the second period Tbn to the length of the first period Tan.

At the time t13, the counter section 30 finishes counting down the pulses of the signal S2 in accordance with the stop signal. The counter section 30 outputs the differential signal S3 indicating a difference value “+100” between the count value in the first period Tan and the count value in the second period Tbn.

In a period from a time t14 to a time t15, the determination section 40 compares the value “+100” of the differential signal S3 and the threshold “±40”. The signal value “+100” of the differential signal S3 does not fall below the first threshold “−40”. The first threshold determination part 41 thus determines that no positive event occurs. The second threshold determination part 42 determines that the signal value “+100” of the differential signal S3 is higher than the second threshold “+40” and detects that the motion of the measurement target causes a negative event to occur.

In a period from the time t15 to a time t16, the determination section 40 generates the motion signal S11 indicating the signal value of the differential signal S3 and the occurrence of a negative event in accordance with the results of the determinations made by the first threshold determination part 41 and the second threshold determination part 42. The bit inversion section 60 performs the inversion process on the bit value of the differential signal S3 and generates the grayscale signal S12. The signal processing unit 130 outputs the motion signal S11 of each of the pixels P generated in the N-th subframe to the outside. The signal processing unit 130 may also output the grayscale signal S12 of each of the pixels P generated in the N-th subframe to the outside. In addition, the signal processing unit 130 causes the memory section 75 to hold the grayscale signal S12 and the motion signal S11 of each of the pixels P in the N-th subframe.

In a period from the time t16 to a time t17, the addition section 70 of the signal processing unit 130 calculates the movement direction of the moving target by using the motion signals S11 in the respective subframes held in the memory section 75. The addition section 70 aligns the grayscale signals S12 of each of the pixels P in a plurality of subframes in accordance with movement of the target and adds and averages the grayscale signals S12 in the respective subframes. The signal processing unit 130 may output the grayscale signal S12 averaged by the addition section 70 to the outside.

In this way, the photodetector 1 according to the present embodiment includes the counter section 30 and the control section 35 each configured to acquire the differential signal S3. The counter section 30 and the control section 35 are provided for each of the pixels P. This makes it possible to detect the differential signal S3 of each of the pixels P and calculate the motion signal S11 and the grayscale signal S12 of the pixel P. It is possible to concurrently obtain the motion signal and the grayscale signal of the same pixel P. It is possible to achieve the photodetector having high detection performance.

In addition, in the present embodiment, a SPAD element is used as the light receiving element 10. This makes it possible to suppress a decrease in detection accuracy in a case of measurement at low illuminance and low contrast. It is possible to accurately detect the motion of the measurement target and output the grayscale value. In addition, a process of averaging grayscale signals makes it possible to improve the S/N ratio and obtain the grayscale signal with less noise.

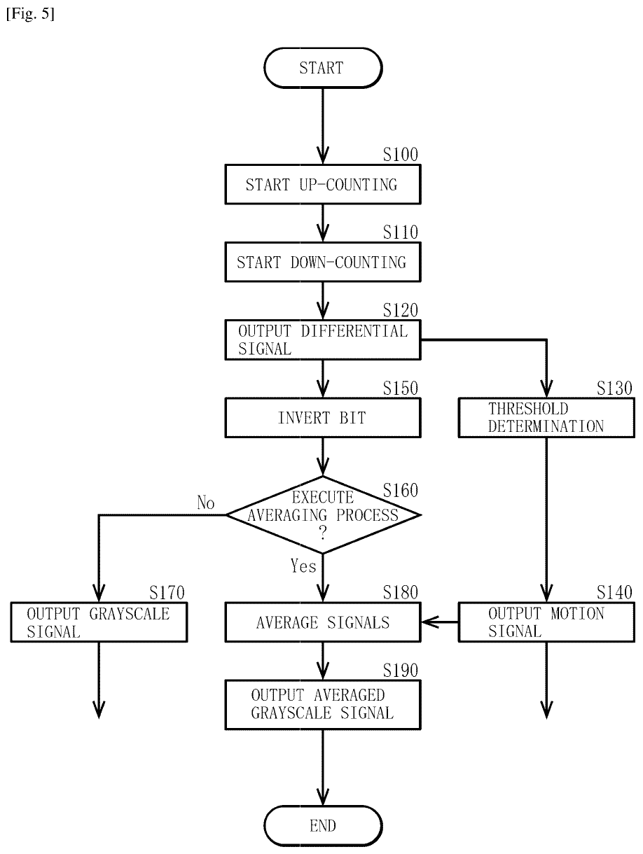

FIG. 5 is a flowchart illustrating an operation example of the photodetector according to the embodiment. The operation example of the photodetector 1 is described with reference to this flowchart of FIG. 5.

In step S100 illustrated in FIG. 5, the count value of the counter section 30 is reset in accordance with the start signal from the control section 35. The counter section 30 starts to count up the pulses of the signal S2 generated in response to reception of a photon. In a case where the count value reaches the reference value (e.g., a full code value “255”), the counter section 30 outputs the overflow signal to the control section 35. In step S110, the counter section 30 starts to count down the pulses of the signal S2.

In step S120, the counter section 30 stops counting down the pulses in accordance with the stop signal from the control section 35. The counter section 30 outputs the differential signal S3 indicating a count result to the determination section 40 and the signal processing unit 130.

In step S130, the determination section 40 compares the signal value of the differential signal S3 and the threshold to determine the presence or absence of the occurrence of an event. In step S140, the determination section 40 outputs, to the signal processing unit 130, the motion signal S11 indicating the signal value of the differential signal S3 and the presence or absence of the occurrence of an event in accordance with a result of the determination. In addition, the determination section 40 outputs the motion signal S11 to the outside of the photodetector 1.

In step S150, the bit inversion section 60 performs the bit inversion process on the differential signal S3 to generate the grayscale signal S12. In step S160, the signal processing unit 130 learns whether or not to execute the process of averaging the grayscale signals S12. In a case where the averaging process is not performed (“No” in step S160), the process proceeds to step S170. In step S170, the signal processing unit 130 outputs the grayscale signal S12 of each of the pixels P to the outside of the photodetector 1. The grayscale signal S12 is generated by the bit inversion section 60.

In a case where the averaging process is performed (“Yes” in step S160), the process proceeds to step S180. It is to be noted that presence or absence of the averaging process may be automatically set by the photodetector 1 or may be designated by a user.

In step S180, the addition section 70 shifts and adds and averages the grayscale signals S12 of each of the pixels P in the respective frames held in the memory section 75 in accordance with the movement direction of the target obtained from the motion signal S11. In step S190, the signal processing unit 130 may output the grayscale signal S12 averaged by the addition section 70 to the outside. After step S190, the photodetector 1 finishes the processes illustrated in the flowchart of FIG. 5.

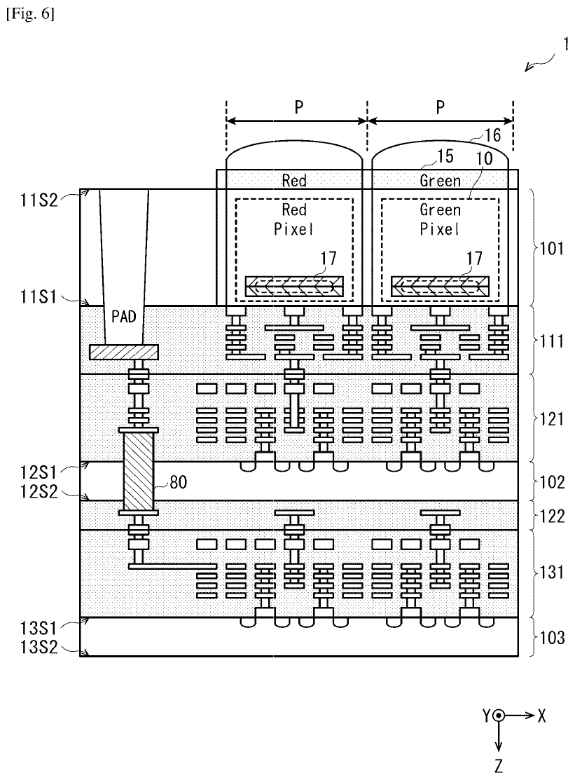

FIG. 6 is a schematic diagram illustrating an example of a cross-sectional configuration of the photodetector according to the embodiment. The photodetector 1 has a configuration in which the first substrate 101, the second substrate 102, and the third substrate 103 are stacked in the Z axis direction. The first substrate 101, the second substrate 102, and the third substrate 103 each include a semiconductor substrate (e.g., a silicon substrate).

As illustrated in FIG. 6, the first substrate 101, the second substrate 102, and the third substrate 103 respectively have first surfaces 11S1, 12S1, and 13S1 and second surfaces 11S2, 12S2, and 13S2. The first surfaces 11S1, 12S1, and 13S1 are provided with transistors. Each of the first surfaces 11S1, 12S1, and 13S1 is an element formation surface on which an element such as a transistor is formed. Each of the first surfaces 11S1, 12S1, and 13S1 is provided with a gate electrode, a gate oxide film, and the like.

The first substrate 101 is provided with the plurality of pixels P each including the light receiving element 10. As schematically illustrated in FIG. 6, each of the pixels P includes a multiplication section 17 (multiplication region) configured to perform avalanche multiplication. A lens section 16, the filter 15, and the like are provided for each of the pixels P on the second surface 11S2 side of the first substrate 101. The lens section 16 condenses light.

As illustrated in FIG. 6, the first surface 11S1 of the first substrate 101 is provided with a wiring layer 111. In addition, the first surface 12S1 of the second substrate 102 is provided with a wiring layer 121. The second surface 12S2 of the second substrate 102 is provided with a wiring layer 122. The first surface 13S1 of the third substrate 103 is provided with a wiring layer 131. Each of the wiring layers 111, 121, 122, and 131 includes, for example, a conductor film and an insulating film. Each of the wiring layers 111, 121, 122, and 131 includes a plurality of wiring lines, vias, and the like. Each of the wiring layers 111, 121, 122, and 131 includes, for example, two or more layers of wiring lines.

Each of the wiring layers 111, 121, 122, and 131 has a configuration in which a plurality of wiring lines is stacked, for example, with an interlayer insulating layer (interlayer insulating film) interposed in between. Each of the wiring layers is formed by using aluminum (Al), copper (Cu), tungsten (W), polysilicon (Poly-Si), or the like. In one example, each of the interlayer insulating layers is formed by using a monolayer film including one of silicon oxide (SiO), silicon nitride (SiN), silicon oxynitride (SiON), or the like, or a stacked film including two or more thereof.

It is to be noted that the first substrate 101 and the wiring layer 111 may be sometimes referred to collectively as the first substrate 101 (or a first circuit layer). In addition, the second substrate 102 and the wiring layers 121 and 122 may be sometimes referred to collectively as the second substrate 102 (or a second circuit layer). The third substrate 103 and the wiring layer 131 may be sometimes referred to collectively as the third substrate 103 (or a third circuit layer).

In the example illustrated in FIG. 6, the first substrate 101 and the second substrate 102 are stacked by joining electrodes with the first surface 11S1 and the first surface 12S1 opposed to each other. Elements such as transistors are formed on the first surface 11S1 and the first surface 12S1. In other words, the first substrate 101 and the second substrate 102 are joined with the respective front surfaces opposed to each other. The second substrate 102 and the third substrate 103 are stacked by joining electrodes with the second surface 12S2 and the first surface 13S1 opposed to each other. Elements such as transistors are formed on the first surface 13S1. In other words, the second substrate 102 and the third substrate 103 are joined with the back surface of the second substrate 102 and the front surface of the third substrate 103 opposed to each other.

In one example, the first substrate 101 and the second substrate 102 are bonded together by joining metal electrodes each including copper (Cu). In other words, the first substrate 101 and the second substrate 102 are bonded together by forming a Cu—Cu junction. In addition, the second substrate 102 and the third substrate 103 are also bonded together by forming, for example, a Cu—Cu junction. It is to be noted that the electrodes used for junction may include, for example, a metal material such as nickel (Ni), cobalt (Co), or tin (Sn) other than copper (Cu). Alternatively, the electrodes may include another material.

The second substrate 102 and the wiring layers 121 and 122 include a plurality of through electrodes 80. Each of the through electrodes 80 is an electrode that penetrates the second substrate 102. The through electrode 80 is formed to extend in the Z axis direction and reach inside of the wiring layer 122 of the second substrate 102. The through electrode 80 includes, for example, tungsten (W), aluminum (Al), cobalt (Co), molybdenum (Mo), ruthenium (Ru), or the like. The through electrode 80 electrically couples a circuit provided on the first surface 12S1 side of the second substrate 102 and a circuit provided on the first surface 13S1 side of the third substrate 103.

The first substrate 101 is provided with a pad (PAD). The pad is an electrode formed by using, for example, aluminum (Al). It is to be noted that the pad may include another metal material. A plurality of pads is disposed in the photodetector 1. Each of the pads may supply, for example, a power supply voltage inputted from the outside to the respective circuits of the first substrate 101 to the third substrate 103.

### Workings and Effects

A photodetector (photodetector 1) according to the present embodiment includes a light receiving element (light receiving element 10) and one input part (input part 31). The light receiving element photoelectrically converts light. The one input part receives the first signal (signal S2) based on electric charge generated by the light receiving element. The photodetector includes a counter section (counter 30) and a control section (control section 35). The counter section is configured to output the second signal (differential signal S3) based on the difference between the number of pulses of the first signal in the first period and the number of pulses of the first signal in the second period. The control section is configured to control the counter section. The counter section and the control section are provided for each of pixels. The pixels each includes the light receiving element.

The photodetector 1 according to the present embodiment includes the counter section 30 configured to acquire the differential signal S3. The counter section 30 and the control section 35 are provided for each of the pixels P. This makes it possible to detect the differential signal of each of the pixels P and obtain the motion signal and the grayscale signal of the pixel P. It is possible to achieve the photodetector having high detection performance.

Next, modification examples of the present disclosure are described. The following assigns the same signs to components similar to those of the embodiment described above and omits descriptions thereof as appropriate.

### 1-1. Modification Example 1

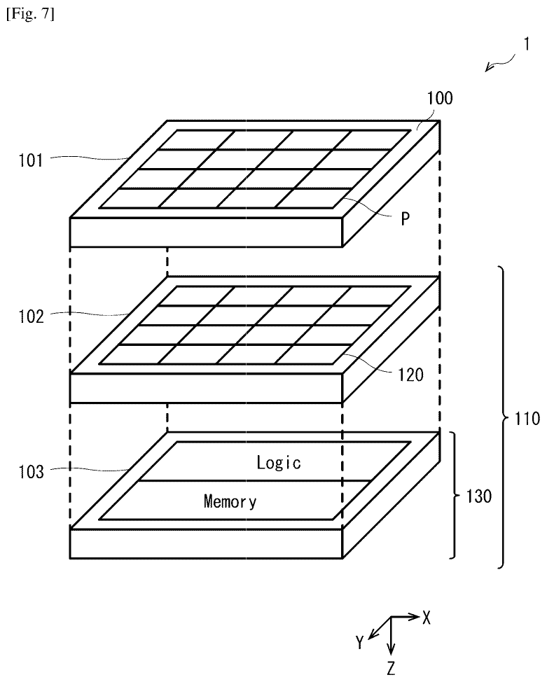

In the embodiment described above, the disposition example of the filter 15 has been described, but the disposition of the filter 15 is not limited to this. In addition, as in the example illustrated in FIG. 7, each of the pixels P does not have to include the filter 15. The photodetector 1 may have a configuration in which the filter 15 such as an RGB color filter is not provided. It is to be noted that each of the pixels P is not limited to a pixel including the light receiving element 10 configured to receive visible light and output a photocurrent as described above. The pixel P may be a pixel including the light receiving element 10 configured to receive invisible light (e.g., infrared light) and output a photocurrent.

### 1-2. Modification Example 2

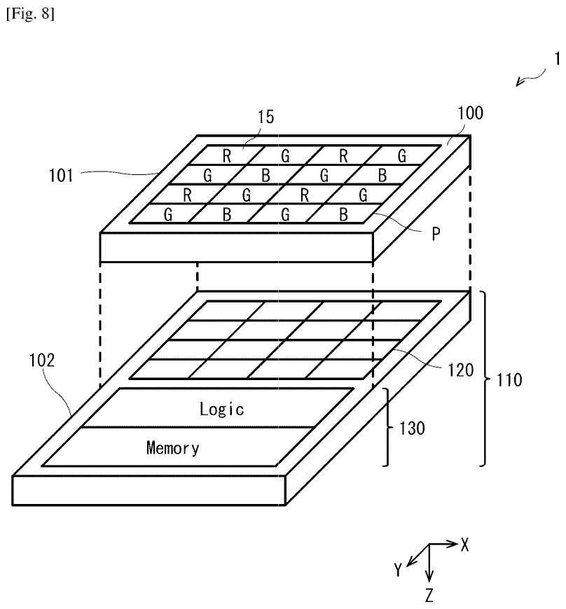

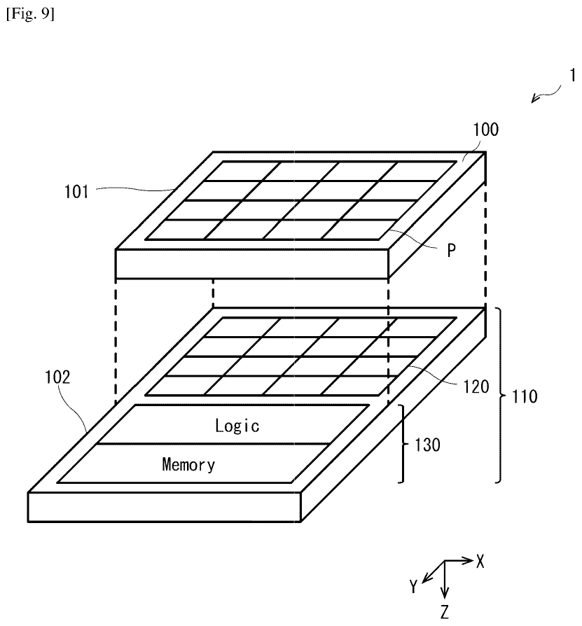

In the embodiment and the modification example described above, the configuration example of the photodetector 1 has been described, but the photodetector 1 may have a configuration in which two substrates are stacked. FIG. 8 is a diagram illustrating a configuration example of a photodetector according to a modification example 2. The photodetector 1 has a configuration (two-layer configuration) in which the first substrate 101 and the second substrate 102 are stacked in the Z axis direction. In this case, for example, the pixel circuit unit 120 and the signal processing unit 130 may be provided in the second substrate 102. It is to be noted that the filter 15 such as an RGB color filter does not have to be disposed in each of the pixels P of the first substrate 101 as illustrated in FIG. 9.

### 1-3. Modification Example 3

In the embodiment described above, the example has been described in which counting is started in synchronization with the synchronization signal. However, the photodetector 1 may start counting by using the start signal asynchronous to the synchronization signal. The photodetector 1 makes it possible to perform a high-speed operation as compared with a case where the photodetector 1 controls a timing of the count operation in synchronization with the synchronization signal.

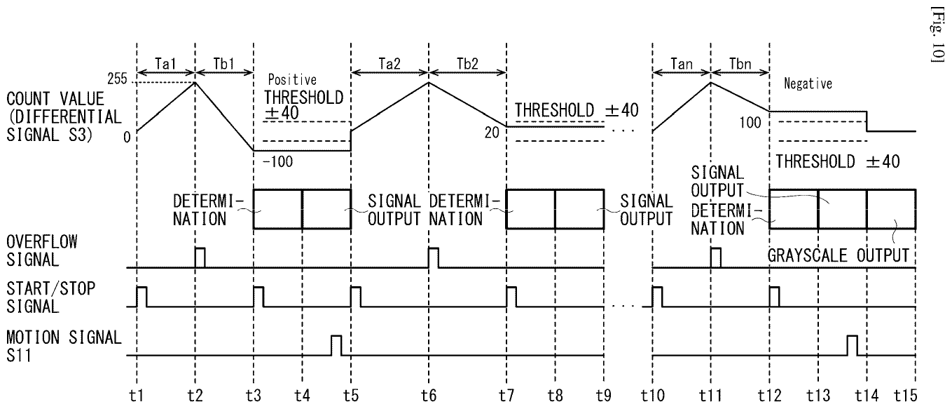

FIG. 10 is a timing chart illustrating an operation example of a photodetector according to a modification example 3. In the example illustrated in FIG. 10, the control section 35 of the photodetector 1 may supply the start signal to the counter section 30 out of synchronization with the synchronization signal. This makes it possible to decrease a time (such as a period from the time t3 to the time t5 illustrated in FIG. 10) from an end timing of the count operation to a start timing of a next count operation as compared with a synchronization operation in FIG. 4. This makes it possible to detect the motion signal and the grayscale signal at high speed.

### 1-4. Modification Example 4

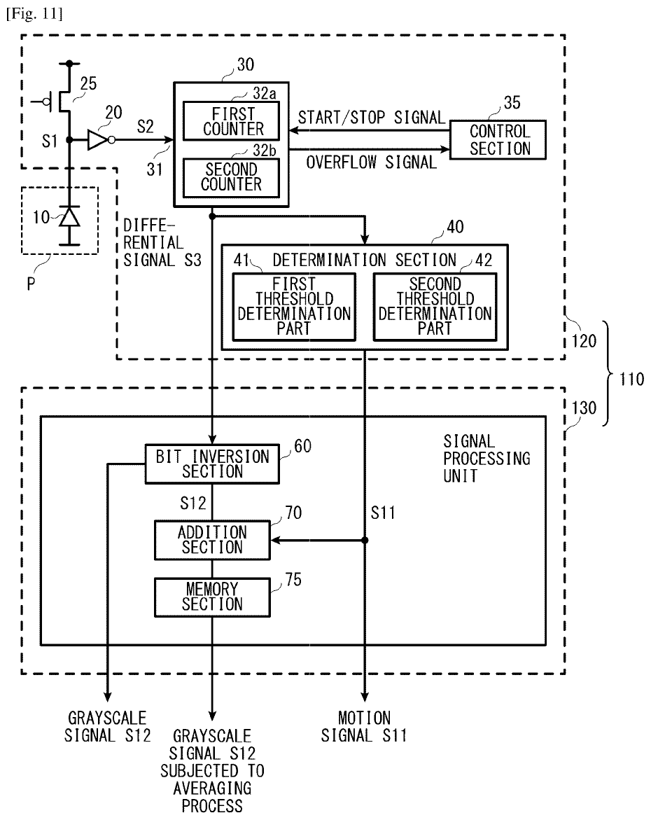

FIG. 11 is a diagram illustrating a configuration example of a photodetector according to a modification example 4. The counter section 30 may include a first counter 32a and a second counter 32b that are each configured to count the signal S2 received by the input part 31. For example, the first counter 32a is configured to count the number of pulses of the signal S2 in the first period Ta. In addition, the second counter 32b is configured to count the number of pulses of the signal S2 in the second period Tb. The counter section 30 may generate and output the differential signal S3 based on the difference between the count value of the first counter 32a and the count value of the second counter 32b. In the present modification example, it is also possible to obtain an effect similar to the effect according to the embodiment described above.

### 3. Usage Examples

For example, the photodetector 1 described above is usable in a variety of cases of sensing light such as visible light, infrared light, ultraviolet light, or X-rays as follows.
Apparatuses that shoot images for viewing such as digital cameras or mobile apparatuses each having a camera function
Apparatuses for traffic use such as onboard sensors that shoot images of the front, back, surroundings, inside, and so on of an automobile for safe driving such as automatic stop and for recognition of a driver's state, monitoring cameras that monitor traveling vehicles and roads, and distance measurement sensors that measure vehicle-to-vehicle distance
Apparatuses for use in home electrical appliances such as televisions, refrigerators, or air-conditioners to shoot images of a user's gesture and bring the appliances into operation in accordance with the gesture
Apparatuses for medical care and health care use such as endoscopes or apparatuses that shoot images of blood vessels by receiving infrared light
Apparatuses for security use such as monitoring cameras for crime prevention or cameras for individual authentication
Apparatuses for beauty use such as skin measurement apparatuses that shoot images of skin and microscopes that shoot images of scalp
Apparatuses for sports use such as action cameras or wearable cameras for sports applications and the like
Apparatuses for agricultural use such as cameras for monitoring the conditions of fields and crops

### 4. Practical Application Examples

### Example of Practical Application to Mobile Body

The technology (the present technology) according to an embodiment the present disclosure is applicable to a variety of products. For example, the technology according to an embodiment of the present disclosure may be achieved as a device mounted on any type of mobile body such as an automobile, an electric vehicle, a hybrid electric vehicle, a motorcycle, a bicycle, a personal mobility, an airplane, a drone, a vessel, or a robot.

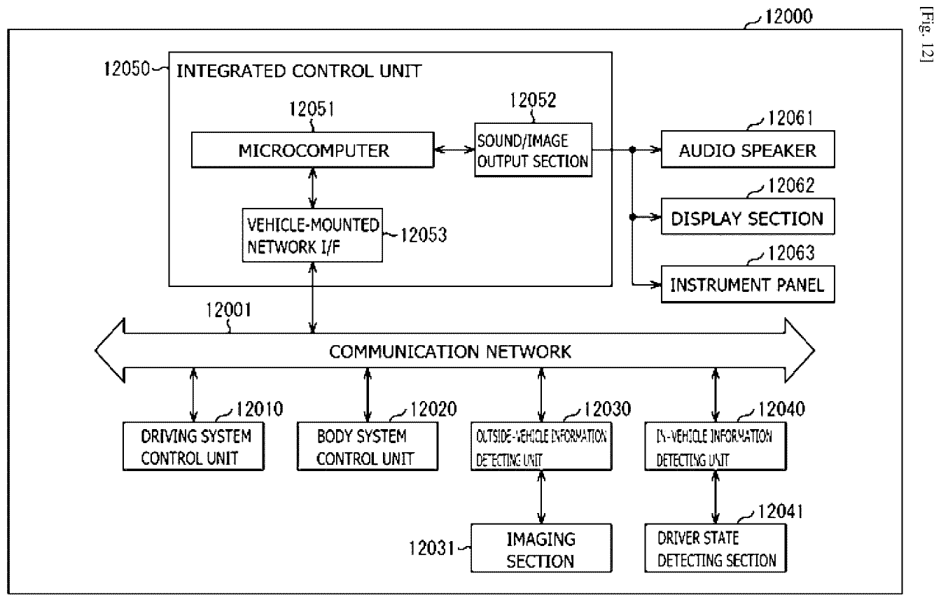

FIG. 12 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 12, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 12, an audio speaker 12061, a display section 12062, and an instrument panel 12063 are illustrated as the output device. The display section 12062 may, for example, include at least one of an on-board display and a head-up display.

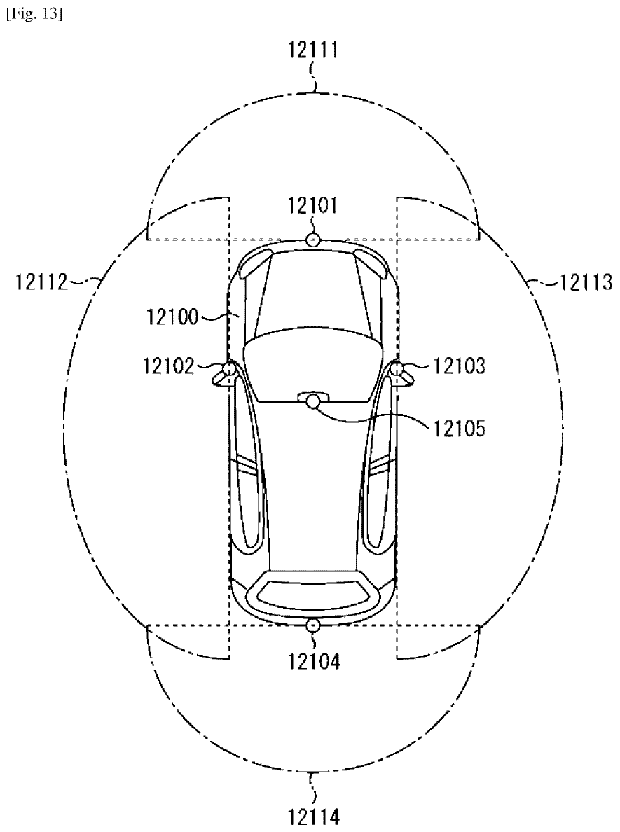

FIG. 13 is a diagram depicting an example of the installation position of the imaging section 12031.

In FIG. 13, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 13 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

The above has described the example of the mobile body control system to which the technology according to an embodiment of the present disclosure may be applied. The technology according to an embodiment of the present disclosure may be applied, for example, to the imaging section 12031 among the components described above. Specifically, for example, the photodetector 1 is applicable to the imaging section 12031. The application of the technology according to an embodiment of the present disclosure to the imaging section 12031 makes it possible to obtain a high-definition shot image and makes it possible to perform highly accurate control using the shot image in the mobile body control system.

### Example of Practical Application to Endoscopic Surgery System

The technology (the present technology) according to an embodiment the present disclosure is applicable to a variety of products. For example, the technology according to an embodiment of the present disclosure may be applied to an endoscopic surgery system.

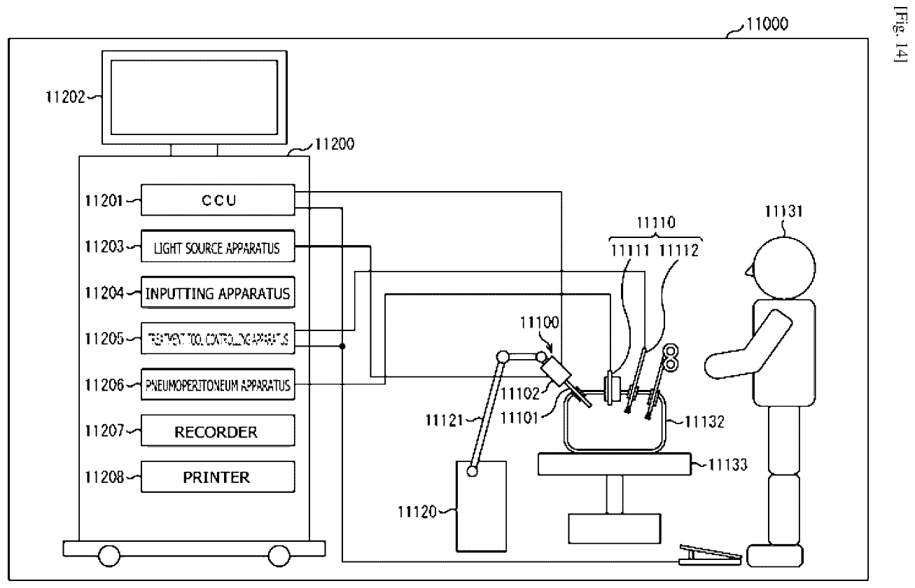

FIG. 14 is a view depicting an example of a schematic configuration of an endoscopic surgery system to which the technology according to an embodiment of the present disclosure (present technology) can be applied.

In FIG. 14, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

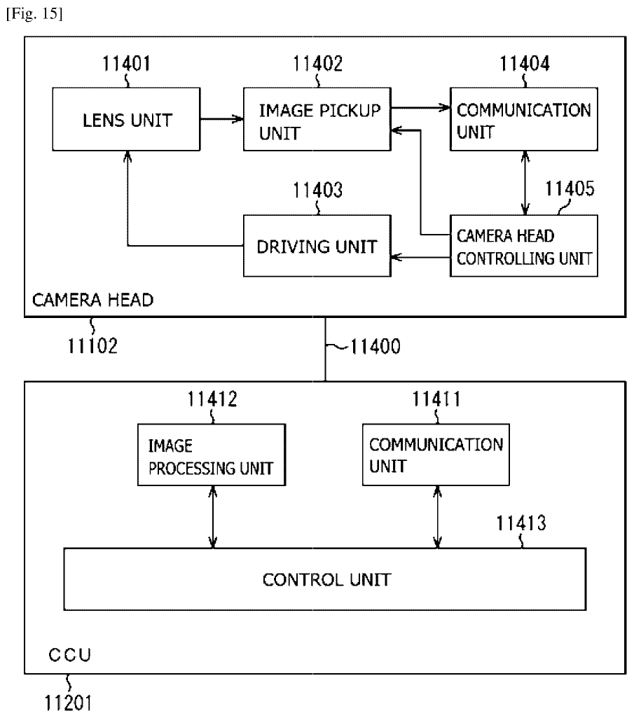

FIG. 15 is a block diagram depicting an example of a functional configuration of the camera head 11102 and the CCU 11201 depicted in FIG. 14.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

The above has described the example of the endoscopic surgery system to which the technology according to an embodiment of the present disclosure may be applied. The technology according to an embodiment of the present disclosure may be favorably applied, for example, to the image pickup unit 11402 provided to the camera head 11102 of the endoscope 11100 among the components described above. The application of the technology according to an embodiment of the present disclosure to the image pickup unit 11402 makes it possible to increase the sensitivity of the image pickup unit 11402 and makes it possible to provide the high-definition endoscope 11100.

Although the present disclosure has been described with reference to the embodiment, the modification examples, the usage examples, and the practical application examples, the contents of the present technology are not limited to the embodiment and the like described above. A variety of modifications are possible. For example, the modification examples described above have been described as modification examples of the embodiment described above, but it is possible to combine the components according to the respective modification examples as appropriate.

A photodetector according to an embodiment of the present disclosure includes: a light receiving element; a counter section; and a control section. The light receiving element is configured to receive light and output a photocurrent. The counter section includes one input part that receives a first signal based on the photocurrent. The counter section is configured to output a second signal based on a difference between a number of pulses of the first signal in a first period and a number of pulses of the first signal in a second period. The control section is configured to control the counter section. The counter section and the control section are provided for each of pixels. The pixels each includes the light receiving element. This makes it possible to obtain the motion signal and the grayscale signal of the pixel. It is possible to achieve the photodetector having high detection performance.

It is to be noted that the effects described herein are merely examples, but not limited to the description. There may be other effects. In addition, an embodiment of the present disclosure may also have configurations as follows.
(1)

A light detecting device, comprising:
a pixel comprising a light receiving element configured to receive light; and
a pixel circuit, comprising:
a counter circuit configured to receive a first signal based on an output of the light receiving element and to output a second signal based on a difference between a number of first signals in a first period and a number of first signals in a second period; and
a control circuit configured to control the counter circuit.
(2)

The light detecting device according to (1), wherein the light receiving element includes a single photon avalanche diode.
(3)

The light detecting device according to (1) or (2), wherein the counter circuit is configured to output a detection signal when the number of first signals in the first period reaches a reference value.
(4)

The light detecting device according to (3), wherein the detection signal indicates an end of the first period.
(5)

The light detecting device according to any one of (3) to (4), wherein the counter circuit includes an up-down counter.
(6)

The light detecting device according to any one of (3) to (5), wherein the control circuit is configured to control the counter circuit based on the detection signal.
(7)

The light detecting device according to any one of (3) to (6), wherein the control circuit is configured to output a stop signal indicating an end of the second period to the counter circuit based on the detection signal.
(8)

The light detecting device according to (7), wherein the control circuit is configured to output the stop signal indicating the end of the second period to the counter circuit to substantially equalize respective lengths of the first period and the second period.
(9)

The light detecting device according to any one of (1) to (8), wherein the control circuit includes a timing generator.
(10)

The light detecting device according to any one of (1) to (9), further comprising a signal processing circuit configured to generate a third signal based on a sum of the number of first signals in the first period and the number of first signals in the second period.
(11)

The light detecting device according to (10), wherein the signal processing circuit includes a bit inversion circuit configured to invert a bit value of the second signal to generate the third signal.
(12)

The light detecting device according to (10) or (11), wherein the signal processing circuit includes a memory configured to hold the third signal.
(13)

The light detecting device according to any one of (10) to (12), wherein the signal processing circuit is configured to average a plurality of the third signals in accordance with the difference between the number of first signals in the first period and the number of first signals in the second period and output the averaged third signal.
(14)

The light detecting device according to any one of (1) to (13), further comprising a plurality of the pixels, wherein the plurality of the pixels includes at least one of a pixel including the light receiving element configured to receive visible light and a pixel including the light receiving element configured to receive non-visible light.
(15)

The light detecting device according to any one of (1) to (14), wherein
the counter circuit includes a first counter and a second counter each configured to count the first signal,
the first counter is configured to count the number of first signals in the first period, and
the second counter is configured to count the number of first signals in the second period.
(16)

The light detecting device according to any one of (1) to (15), comprising:
a first substrate including a plurality of the pixels; and
a second substrate including a plurality of the pixel circuits, the first substrate being stacked on the second substrate.
(17)

The light detecting device according to any one of (1) to (16), wherein the pixel circuit of a plurality of pixel circuits is positioned directly below the pixel of a pixel array.
(18)

A light detecting device, comprising:
a pixel comprising a light receiving element; and
a pixel circuit comprising a counter circuit and a control circuit,
wherein the light detecting device is configured to detect an intensity signal and a motion signal.
(19)

An electronic apparatus, comprising:
a signal processor; and
a light detecting device, comprising:
a pixel comprising a light receiving element configured to receive light; and
a pixel circuit, comprising:
a counter circuit configured to receive a first signal based on an output of the light receiving element and output a second signal based on a difference between a number of first signals in a first period and a number of first signals in a second period; and
a control circuit configured to control the counter circuit.
(20)

A photodetector including:
a light receiving element configured to receive light and output a photocurrent;
a counter section including one input part that receives a first signal based on the photocurrent, the counter section being configured to output a second signal based on a difference between a number of pulses of the first signal in a first period and a number of pulses of the first signal in a second period; and
a control section configured to control the counter section, in which
the counter section and the control section are provided for each of pixels, the pixels each including the light receiving element.
(21)

The photodetector according to (20), in which the light receiving element includes a single photon avalanche diode.
(22)

The photodetector according to (20) or (21), in which the counter section is configured to output a detection signal indicating that the number of pulses of the first signal in the first period reaches a reference value.
(23)

The photodetector according to (22), in which the detection signal includes a signal indicating an end of the first period.
(24)

The photodetector according to (22) or (23), in which the counter section includes an up-down counter.
(25)

The photodetector according to any one of (22) to (24), in which the control section is configured to control the counter section on the basis of the detection signal.
(26)

The photodetector according to any one of (22) to (25), in which the control section is configured to output a signal indicating an end of the second period to the counter section on the basis of the detection signal.
(27)

The photodetector according to any one of (22) to (26), in which the control section is configured to output the signal indicating the end of the second period to the counter section to equalize respective lengths of the first period and the second period.
(28)

The photodetector according to any one of (22) to (27), in which the control section includes a timing generator.
(29)

The photodetector according to any one of (20) to (28), including a signal processing unit configured to generate a third signal on the basis of the second signal outputted from the counter section, the third signal being based on a sum of the number of pulses of the first signal in the first period and the number of pulses of the first signal in the second period.
(30)

The photodetector according to (29), in which the signal processing unit includes a bit inversion section configured to invert a bit value of the second signal.
(31)

The photodetector according to (29) or (30), in which the signal processing unit includes a memory section configured to hold the third signal.
(32)

The photodetector according to any one of (29) to (31), in which the signal processing unit is configured to average a plurality of the third signals in accordance with the difference between the number of pulses of the first signal in the first period and the number of pulses of the first signal in the second period and output the averaged third signal.
(33)

The photodetector according to any one of (20) to (32), including a plurality of pixels each including the light receiving element, in which
the plurality of pixels includes at least one of a pixel including the light receiving element configured to receive visible light and output a photocurrent or a pixel including the light receiving element configured to receive invisible light and output a photocurrent.
(34)

The photodetector according to any one of (20) to (33), in which
the counter section includes a first counter and a second counter each configured to count the first signal received by the input part,
the first counter is configured to count the number of pulses of the first signal in the first period, and
the second counter is configured to count the number of pulses of the first signal in the second period.
(35)

The photodetector according to any one of (20) to (34), including a generation section configured to generate the first signal based on the photocurrent.
(36)

The photodetector according to (35), in which the generation section is coupled to the input part and configured to output the first signal to the input part.
(37)

The photodetector according to (35) or (36), in which the generation section includes an inverter.
(38)

The photodetector according to any one of (20) to (37), including:
a first substrate including a plurality of the light receiving elements; and
a second substrate including the counter section and the control section, the second substrate being stacked on the first substrate.

It should be understood by those skilled in the art that various modifications, combinations, sub-combinations and alterations may occur depending on design requirements and other factors insofar as they are within the scope of the appended claims or the equivalents thereof.

### REFERENCE SIGNS LIST

1 photodetector (light detecting device)
10 light receiving element
20 generation section (generation circuit)
25 supply section (supply circuit)
30 counter section (counter circuit)
35 control section (control circuit)
40 determination section (determination circuit)
60 bit inversion section (bit inversion circuit)
70 addition section (addition circuit)
75 memory section
100 pixel unit
110 processor
120 pixel circuit unit
130 signal processing unit

1. A light detecting device, comprising:
a pixel comprising a light receiving element configured to receive light; and
a pixel circuit, comprising:
a counter circuit configured to receive a first signal based on an output of the light receiving element and to output a second signal based on a difference between a number of first signals in a first period and a number of first signals in a second period; and
a control circuit configured to control the counter circuit.

2. The light detecting device according to claim 1, wherein the light receiving element includes a single photon avalanche diode.

3. The light detecting device according to claim 1, wherein the counter circuit is configured to output a detection signal when the number of first signals in the first period reaches a reference value.

4. The light detecting device according to claim 3, wherein the detection signal indicates an end of the first period.

5. The light detecting device according to claim 3, wherein the counter circuit includes an up-down counter.

6. The light detecting device according to claim 3, wherein the control circuit is configured to control the counter circuit based on the detection signal.

7. The light detecting device according to claim 3, wherein the control circuit is configured to output a stop signal indicating an end of the second period to the counter circuit based on the detection signal.

8. The light detecting device according to claim 7, wherein the control circuit is configured to output the stop signal indicating the end of the second period to the counter circuit to substantially equalize respective lengths of the first period and the second period.

9. The light detecting device according to claim 6, wherein the control circuit includes a timing generator.

10. The light detecting device according to claim 1, further comprising a signal processing circuit configured to generate a third signal based on a sum of the number of first signals in the first period and the number of first signals in the second period.

11. The light detecting device according to claim 10, wherein the signal processing circuit includes a bit inversion circuit configured to invert a bit value of the second signal to generate the third signal.

12. The light detecting device according to claim 10, wherein the signal processing circuit includes a memory configured to hold the third signal.

13. The light detecting device according to claim 10, wherein the signal processing circuit is configured to average a plurality of the third signals in accordance with the difference between the number of first signals in the first period and the number of first signals in the second period and output the averaged third signal.

14. The light detecting device according to claim 1, further comprising a plurality of the pixels, wherein
the plurality of the pixels includes at least one of a pixel including the light receiving element configured to receive visible light and a pixel including the light receiving element configured to receive non-visible light.

15. The light detecting device according to claim 1, wherein
the counter circuit includes a first counter and a second counter each configured to count the first signal,
the first counter is configured to count the number of first signals in the first period, and
the second counter is configured to count the number of first signals in the second period.

16. The light detecting device according to claim 1, comprising:
a first substrate including a plurality of the pixels; and
a second substrate including a plurality of the pixel circuits, the first substrate being stacked on the second substrate.

17. The light detecting device according to claim 1, wherein the pixel circuit of a plurality of pixel circuits is positioned directly below the pixel of a pixel array.

18. A light detecting device, comprising:
a pixel comprising a light receiving element; and
a pixel circuit comprising a counter circuit and a control circuit,
wherein the light detecting device is configured to detect an intensity signal and a motion signal.

19. An electronic apparatus, comprising:
a signal processor; and
a light detecting device, comprising:
a pixel comprising a light receiving element configured to receive light; and
a pixel circuit, comprising:
a counter circuit configured to receive a first signal based on an output of the light receiving element and to output a second signal based on a difference between a number of first signals in a first period and a number of first signals in a second period; and
a control circuit configured to control the counter circuit.
